(19) United States
(12) Patent Application Publication
(10) Pub. No.: US 2008/0311337 A1
(43) Pub. Date: Dec. 18, 2008

(54) SUBSTRATES COATED WITH ORGANOSILOXANE NANOFIBERS, METHODS FOR THEIR PREPARATION, USES AND REACTIONS THEREOF

(76) Inventors: Jonathan Gordon Conn Veinot, Edmonton (CA); De-ann Rollings, Edmonton (CA); Shufen Tsoi, Edmonton (CA); Jeremy Sit, Edmonton (CA)

Correspondence Address: BERESKIN AND PARR, 40 KING STREET WEST, BOX 401, TORONTO, ON, M5H 3Y2, CA

(21) Appl. No.: 12/128,298

(22) Filed: May 28, 2008

Related U.S. Application Data
(60) Provisional application No. 60/940,435, filed on May 28, 2007.

(51) Int. Cl. B32B 33/00; H01L 21/31

(52) U.S. Cl. 428/90; 438/780; 257/E21.24

(57) ABSTRACT

The present disclosure relates to method of forming organosiloxane nanofibers on substrates, in particular by contacting an activated substrate with a vapor comprising vinyltrichlorosilane. The disclosure relates to the substrates thus formed and to various uses thereof. The disclosure further relates to a general method of preparing hydrophilic siloxane nanofibers on a substrate comprising by annealing any substrate coated with organosiloxane nanofibers under conditions to remove substantially all of the organic portions of the organosiloxane nanofibers.

The present disclosure relates to methods of preparing substrates comprising a coating containing organosiloxane nanofibers, the substrates prepared using these methods and various uses of and reactions with these substrates.

### BACKGROUND OF THE DISCLOSURE

One-dimensional (1D) materials such as nanofibers are the subject of fundamental and technological interest because of their unique properties arising from high aspect ratios, large surface areas, as well as their optical and electronic response. Notable devices that incorporate 1-D materials include ultraviolet lasers,¹ optical switches,² field effect transistors,³ diodes,⁴ and sensors.^{3, 5-7} More specifically, silicon oxide nanofibers have demonstrated device application as emissive materials, in nanoelectronics and in integrated optical devices. Examples of such applications include: low dimensional waveguides for functional microphotonics, scanning near field optical microscopy, optical interconnects on optical microchips, biosensors, and optical transmission antennae. ⁸⁻¹¹

To date, procedures for preparing nanofibers of various materials have included vapor-liquid-solid growth (VLS),^{2 12, 13} template directed synthesis,^{2, 14 15} kinetic controlled synthesis,^{2, 6, 16} electrospinning,¹⁷⁻²⁰ substrate etching, and polymer drawing.²¹ While these methods are versatile and provide for proof-of-concept experiments, each has its own limitations. For example, the VLS approach to tailoring fiber dimensionality uses pre-deposited nanoparticle catalyst arrays that ultimately remain encapsulated in the nanofiber tip potentially altering material properties and hindering future utility. Other limitations such as low yields and the necessity for complex, time consuming lithographic procedures are also significant considerations of these methods.²

Surface induced polymerization (SIP) is a versatile technique for controlling surface properties. Materials prepared using SIP have found utility in various applications such as sensors,²² biomedical devices,^{23 24} and chromatographic stationary phases.²⁵ Moreover, SIP provides materials of controlled polydispersity and high graft density via moderate reaction conditions suitable for preparation of well-defined, functional nanomaterials. Plasma induced polymerization (PIP) is a subset of SIP, where plasma is used to activate a surface that subsequently induces polymerization. Advantages of PIP are its ease of substrate activation, limited material contamination, and rapid processing times. PIP has been employed for synthesis of thin films and coatings²⁶⁻³⁰.

The preparation of monolayer and thin films of alkyltrichlorosilane reagents on oxide surfaces has been reported;³¹⁻³⁸ however these previous contributions aim to minimize polymer aggregation via minimal inclusion of moisture and typically employ solution-based procedures. Any comments on polymer aggregation are typically limited to its prevention rather than exploitation to form 1D materials.^{35, 37, 39}

The vapor phase deposition of silicone nanofilaments from trichloroalkyl silanes, specifically trichlormethylsilane, optionally in the presence of a trichloroarylsilane, and in the presence of equal amounts of water vapor has been reported for the preparation of superhydrophobic coatings.⁴⁸ Superhydrophobic materials were defined as those having contact angles of higher than about 150°.

### SUMMARY OF THE DISCLOSURE

In the present disclosure, the straightforward, vapor-phase, polymerization of vinyltrichlorosilane to provide well-defined organosiloxane nanofibers of varied dimensionality has been demonstrated. Nanofiber formation was consciously promoted by employing dry or chemical etching as a means to induce vapor-phase surface polymerization while also making no effort to exclude adventitious surface adsorbed water from the reaction chamber.

Accordingly, the present disclosure includes a method of coating an oxide substrate with organosiloxane nanofibers comprising exposing an activated oxide substrate to vapor comprising vinyltrichlorsilane under conditions for the formation of the organosiloxane nanofibers.

Also included within the present disclosure is a substrate coated with organosiloaxane nanofibers prepared from vinyltrichlorsilane and various uses of and objects and materials comprising these substrates.

The nanofibers of the present disclosure advantageously contain a vinyl functional group. This functional group reacts with molecules to permit their attachment to the substrate via the organosiloxane coating. Examples of molecules that one may wish to attach to the surface of a substrate, include, but are not limited to biomolecules (e.g. DNA, RNA, proteins, peptides or carbohydrates), nanoparticles and polymers. Accordingly, the method of coating an oxide substrate with organosiloxane nanofibers of the present disclosure further includes reacting the coated substrate under conditions for the attachment of a molecule of interest to the substrate via reaction with the vinyl group from the vinyltrichlorosilane.

The present disclosure also includes a general method of preparing hydrophilic siloxane nanofibers on a substrate comprising

(a) obtaining any substrate coated with organosiloxane nanofibers; and

(b) calcining the substrate under conditions to remove substantially all of the organic portions of the organosiloxane nanofibers.

Other features and advantages of the present disclosure will become apparent from the following detailed description. It should be understood, however, that the detailed description and the specific examples while indicating preferred embodiments of the disclosure are given by way of illustration only, since various changes and modifications within the spirit and scope of the disclosure will become apparent to those skilled in the art from this detailed description.

### BRIEF DESCRIPTION OF THE DRAWINGS

The disclosure will now be described in relation to the drawings in which:

FIG. 1 shows oblique and side view SEM micrographs of a: A. high areal density, intertwined network of long fibers showing a ca. 400 nm packed layer. B. moderate areal density array of ca. 150 nm long fibers. C. low areal density, 100 nm fibers highlighting the uniformity of fiber diameters.

FIG. 2 shows the influence of reagent structure on film morphology. Insets are aqueous advancing contact angle measurements and reagent structures. A. HTS, B. 5-hexenyltrichlorosilane, C. VTMS, D. VTS.

FIG. 3 shows a pictorial representation outlining a proposed mechanism for nanofiber formation in one embodiment of the present disclosure.

FIG. 4a. shows an SEM of poly(vinylsiloxane) nanofibers grown on a previously RIE'd greige sample; b. shows an SEM of water droplet on a coated greige Kevlar® substrate.

FIG. 5 is a schematic of a continuous flow reaction apparatus according to one embodiment of the present disclosure.

FIG. 6 is a schematic showing the top view of the apparatus shown in FIG. 5 without the cover and with a shelf supporting the substrate.

FIGS. 7a. and b. show SEM of a RIE'd, scoured Kevlar® substrate exposed to a continuous flow of both VTS/Ar and H₂O/Ar. c. is an SEM showing H₂O beading on the surface of the poly(vinyl siloxane) nanofiber coated Kevlar® substrate.

FIG. 8 is a schematic illustration of a frame (1) to be used to support a substrate in an intermediate sized (e.g. 16″×16″) reaction chamber according to one embodiment of the present disclosure.

FIG. 9 is a schematic illustration of a proposed apparatus designed to accommodate intermediate sized (e.g. 16″×16″) substrates according to one embodiment of the present disclosure.

FIG. 10 is a schematic illustration of an alternative apparatus design modified that includes a perforated shelf for uniform dispersion of RSiCl₃/Ar according to one embodiment of the present disclosure.

FIG. 11 is a schematic illustration of an alternative apparatus for intermediate sized (e.g. 16″×16″) substrates according to one embodiment of the present disclosure. In this embodiment, the inlets have been relocated to the sides of the chamber, and the outlet has been moved to the top.

### DETAILED DESCRIPTION OF THE DISCLOSURE

Organosilicon nanofibers of controllable dimensions of varying diameters and lengths have been synthesized from the surface induced polymerization of vinyltrichlorosilanes on surfaces with high hydroxyl group concentration.

Accordingly, the present disclosure includes a method of coating an oxide substrate with organosiloxane nanofibers comprising exposing an activated oxide substrate to vapor comprising vinyltrichlorsilane under conditions for the formation of the organosiloxane nanofibers.

By “oxide substrate” as used herein, it is meant that the substrate is any suitable material comprising reactive oxygen functionalities, for example, hydroxyl groups. In an embodiment of the disclosure, the substrate is activated by treatment under conditions to activate surface functional groups for reaction with the vinyltrichlorosilane. Conditions to activate surface functional groups comprise saturating the surface with hydroxyl moieties. In embodiments of the invention, the conditions to activate surface functional groups comprise exposure to oxygen plasma or placement in a piranha bath. A piranha bath comprises a solution of sulfuric acid:hydrogen peroxide (3:1) and is appropriate for glass or other materials resistant to degradation by these ingredients.

In embodiments of the disclosure, the substrate is selected from metal, silicon-based materials, titanium-based materials, germanium-based materials, aluminum-based materials, biodegradable materials, construction materials, inorganic materials and organic materials. In other embodiments of the disclosure, the substrate is selected from silicon wafers, titanium wafers, germanium wafers, fiber optic cables, capillary tubes, colloidal beads, glass, ceramics, paper, wood, fabrics, cellulose, cellulose derivatives, semiconductors, stone, concrete, marble, bricks and tiles. In specific embodiments of the disclosure, the substrate is a silicon-based material, such as silicon wafers or glass. In another embodiment of the disclosure, the substrate is a fabric. For example, the fabric may be any fabric for which it is desirable to increase the hydrophobicity, such as water-proof or water-resistant fabrics. One non-limiting example of such fabrics are those comprising a class of heat-resistant and strong synthetic fibers known as aromatic polyamides or aramids. These fabrics include, but are not limited to, fabrics known as Kevlar® (comprising para-aramid synthetic fibers), Nomex® (comprising meta-aramid synthetic fibers) and Technora® (comprising aromatic copolyamid fibers).

In a further embodiment of the present disclosure, the fabric is Kevlar®. Polysiloxane nanofibers of various lengths and densities have been grown on Kevlar fabrics provided by Barrday Inc. (Cambridge, Ontario, Canada). More specifically, greige, scoured, unidimensional and polyethylene glycol-treated Kevlar® have supported high density polysiloxane nanofiber formation on the substrate surface. Additionally, all of the above mentioned fabrics have qualitatively exhibited high contact angles.

In embodiments of the disclosure, the conditions for the formation of the organosiloxane nanofibers comprises exposing the substrate to vinyltrichlorosilane vapor in an inert atmosphere without the exclusion of surface adsorbed water. The surface adsorbed water is the water absorbed on the reaction vessel or substrate from the air and depends on the atmospheric humidity. By inert atmosphere, it is meant in an atmosphere of an inert gas, such as argon.

It is an embodiment of the disclosure that the substrate is exposed to vinyltrichlorosilane vapor at a reduced pressure of from about 100 Torr to about 150 Torr, suitably about 125 Torr. In this embodiment, the substrate and reaction vessel are suitably dried under conditions to substantially remove surface-adsorbed water and then an effective amount of water is added to the reaction vessel prior to the addition of vinyltrichlorosilane. An “effective amount of water” as used herein means an amount effective to allow or promote the formation of organosiloxane nanofibers on the substrate. The effective amount of water required will depend on the size of the reaction vessel and on the reaction pressure that is utilized, but will suitably be about 45 μL to about 55 μL, more suitably about 50 μL, for a reaction vessel volume of about 2 L. In a further embodiment, the water is added to the vessel a suitable amount of time prior to the addition of the vinyltrichlorosilane. The suitable amount of time will be a time sufficient to allow the water vapor to equilibrate in the reaction vessel, for example about 5 minutes. Accordingly, in this embodiment of the present disclosure, the conditions for the formation of the organosiloxane nanofibers comprise drying a reaction vessel, drying an activated substrate, inserting the substrate in the vessel under an inert atmosphere and maintaining said inert atmosphere, adding an effective amount of water to the vessel and allowing water vapor to equilibrate, reducing the pressure in the reaction vessel, adding the substrate to the vessel and exposing the substrate to vinyltrichlorosilane vapor. Further, it is another embodiment that the substrate is exposed to the vinyltrichlorosilane vapor for about 0.15 hour to about 1.5 hours, suitably about 1 hour. In another embodiment, the concentration of vinylchlorosilane is from about 0.034 mmol/cm² to about 1 mmol/cm², suitably about 0.137 mmol/cm². Suitably the vinyltrichlorosilane is added to the reaction vessel a time sufficient to allow it to equilibrate, for example about 5 minutes, before exposure to the substrate.

It is another embodiment of the disclosure that the substrate is exposed to vinyltrichlorosilane vapor at atmospheric pressure. To increase the rate of addition of the vinyltrichlorosilane at atmospheric pressure, and therefore increase the reaction rate, an inert carrier gas, such as argon is used to transport the vinyltrichlorosilane into the reaction vessel. This may be done, for example, by bubbling the carrier gas through a solution, suitably a neat solution, of the vinyltrichlorosilcane into the reaction vessel. In an embodiment, the vinyl trichlorosilane/Ar is added to the reaction vessel at a rate of about 0.01 to about 1 mL/min. In this embodiment of the present disclosure, the water may be added to the reaction vessel by either adding the water to the substrate, for example about 1 to about 5% (w/w) water may be added to the substrate, or the water is added via a carrier gas, for example at a rate of about 0.001 to about 3 mL/hour. Accordingly, in this embodiment of the present disclosure, the conditions for the formation of the organosiloxane nanofibers comprise drying a reaction vessel, drying an activated substrate, inserting the substrate in the vessel under an inert atmosphere and maintaining said inert atmosphere, and adding a suitable amount of water to the reaction vessel, either prior to, or simultaneously with, adding the vinyltrichlorosilane to the reaction vessel suitably via a carrier gas that has been passed through a solution of the vinyltrichlorosilane. Suitably the vinyl trichlorosilane is added to the reaction vessel a time sufficient to allow it to equilibriate, for example about 6-20, minutes before exposure to the substrate.

The term “reaction vessel” as used herein refers to any container in which the method of the disclosure can be performed. Suitably the reaction vessel comprises an enclosable chamber, said chamber having one or more sealable ports for the addition or removal of the substrates, reagents and products.

The term “equilibriate” as used herein means that a condition of substantially uniform distribution of a material is achieved.

The present disclosure also includes a substrate coated with silicone nanofibers prepared from vapor phase polymerization of vinyltrichlorosilane. In embodiments of the disclosure. The nanofibers have a diameter of about 20 nm to about 70 nm, suitably about 35 nm. In further embodiments, the substrate coated with organosiloxane nanofibers has an advancing aqueous contact angle of about 90° to about 140°, typically 130°. In still further embodiments, the substrate coated with organosiloxane nanofibers also comprises a wetting layer on the surface of the substrate. By “wetting layer” it is meant a film or coating of silicone polymer that forms across the surface of the substrate. Suitably the wetting layer has a thickness of about 25 nm to about 100 nm. The wetting layer contributes to the passivation of the substrate for applications where the substrate may not be compatible with the environment in which it is to be used, for example, in biological systems. In another embodiment of the present disclosure, the nanofiber coating on the substrate has a thickness of about 100 nm to about 8 μm.

It is an embodiment of the disclosure that the substrate coated with organosiloxane nanofibers is prepared using the method of the present disclosure.

The present disclosure further includes objects and materials coated with silicone nanofibers prepared from vapor phase polymerization of vinyltrichlorosilane. Suitably these devices and materials may be anything for which it is desirable to change the wettability of its surfaces, in particular to make the surface more hydrophobic. Such objects and materials include, but are not limited to windows, fabrics, metal surfaces of for example cars or ships, biosensors and electronic or optical devices. Specific objects include, for example, car windshields, ultraviolet lasers, optical switches, field effect transistors, diodes, optical interconnects on optical microchips, optical transmission antennae and fabrics, such as those comprising aramid fibres (for e.g. Kevlar®).

The nanofibers of the present disclosure advantageously contain a vinyl functional group. This functional group reacts with molecules to permit their attachment to the substrate. Accordingly, the method of coating an oxide substrate with nanofibers of the present disclosure further includes reacting the coated substrate under conditions for the attachment of a molecule of interest to the substrate via reaction with the vinyl group from the vinyltrichlorosilane. In embodiments of the invention, the molecule of interest is for example, but not limited to, biomolecules (e.g. DNA, RNA, proteins, peptides or carbohydrates), nanoparticles or polymers. The term “attachment” as used herein means that the molecules of interest are adhered to the substrate, for example, through electrostatic, hydrogen-bonding, bioaffinity, covalent interactions, hydrophobic interestions or combinations thereof, so that the molecule is not removed from the surface in the conditions or environment that the substrate is to be used. Methods of reacting functional groups, such as amines, hydroxyl, thiol or halogen, to form attachments with vinyl groups are known to those skilled in the art. See, for example, Wasserman, S. R. et al. Langmuir 1989, 5, 1074-1087 and March, J. Advanced Organic Chemistry: Reactions, Mechanisms, and Structure, 4^{th} Ed. 1992, John Wiley & Sons, New York

Treatment of a substrate possessing the organosiloxane nanofibers as described here under calcining reaction conditions, provided a material that retained the fiber structure, however, x-ray photoelectron spectroscopic (XPS) analysis showed that only a trace amount of carbon material was retained. Therefore substantially all of the organic portions were lost to provide a highly hydrophilic material, with an advancing aqueous contact angle of <5°. Such materials are highly refractive materials that find many applications, including, for example, in catalytic converters. The method of preparing such materials can be applied to any organosiloxane nanofibers on any substrate.

Accordingly the present disclosure further includes a method of preparing hydrophilic siloxane nanofibers on a substrate comprising

(a) obtaining a substrate coated with organosiloxane nanofibers; and

(b) calcining the substrate under conditions to remove substantially all of the organic portions of the organosiloxane nanofibers.

The substrate comprising organosiloxane nanofibers may be obtained using a method known in the art, for example, as described in Zimmermann, J.; Seeger, S.; Artus, F.; Jung, S., PCT Patent Application Publication No. WO2004/113456, Jun. 23, 2004, or using a method as described in the present disclosure.

The conditions to remove substantially all of the organic portions of the organosiloxane nanofibers include heating at temperatures ranging from about 380-500° C., for about 0.5-1.5 hours suitably about 1 hour, in air. Morphology of fibers is maintained when heated to 1100° C.

The terms “a” and “an” as used herein can mean one or more than one.

In understanding the scope of the present disclosure, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Finally, terms of degree such as “substantially”, “about” and “approximately” as used herein mean a reasonable amount of deviation of the modified term such that the end result is not significantly changed. These terms of degree should be construed as including a deviation of at least ∓5% of the modified term if this deviation would not negate the meaning of the word it modifies.

The following non-limiting examples are illustrative of the present disclosure:

### EXAMPLES

### Example 1

### Nanofiber Growth on Si Wafers

In preparation for nanofiber growth, n-doped Si (100) wafers (Evergreen Semiconductor Materials) bearing native oxide surfaces were exposed to oxygen plasma (RIE) in a Plasmalab Microetch RIE 80. This RIE treatment serves a dual purpose; it removes trace organic surface impurities and chemically activates the substrate toward VTS reagents by saturating the surface with hydroxyl moieties. The substrates could also be cleaned and activated by placing them in a 3:1 solution of concentrated sulphuric acid:30% hydrogen peroxide for at least 30 minutes. This solution is commonly known as a piranha bath.

After activation substrates were placed in a vacuum oven at temperatures exceeding >120° C. for 1 h then cooled to room temperature in vacuum oven and remained in the oven until placed in the reaction chamber or vessel. Vinyltrichlorosilane (VTS), vinyltrimethoxysilane (VTMS), hexyltrichlorosilane (HTS) (Aldrich Chemical Co.), and 5-hexenyltrichlorosilane (Petrach Chemical Co.) were used as received.

For a typical nanofiber synthesis, activated silicon substrates were placed inside a glass desiccator with an adapted vacuum manifold cover. The chamber was repeatedly evacuated and backfilled with Ar (3×) prior to final evacuation to reaction pressure (125 Torr).⁴⁰ The Si substrate was covered with a tight sealing, custom designed glass shield and 1.5 mmole of VTS vapor was introduced into the reaction vessel. After 10 minutes the glass shield was raised and the activated substrate was exposed to reagent vapor for 1 hour. Modified substrates were subsequently removed and stored in ambient conditions. All functionalized wafers were evaluated using scanning electron microscopy (SEM) and energy dispersive X-ray spectroscopy (EDX) using a JOEL 6301F microscope. FT-IR spectroscopy was conducted with a Bruker Vertex 700 Infrared Spectrometer using a “Seagull Variable Angle Accessory”, Time of flight secondary ion mass spectrometry (TOF-SIMS) using an Ion ToF IV-100, and X-ray photoelectron spectroscopy (XPS) with a Kratos Axis 165 instrument. Surface aqueous wettability was evaluated with a First Ten Angstroms FTA100 Series contact angle/surface energy analysis system.

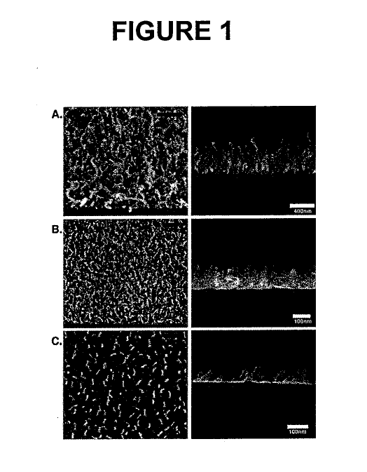

SEM micrographs of VTS exposed substrates show well-defined, robust nanofibers of various densities, polydispersities, and lengths (FIG. 1). Fiber formation and morphology are the result of an interplay between reagent concentration and partial pressure, atmospheric homogeneity, exposure time, and water concentration. As with the monolayer functionalization using VTSS,⁴¹ the quantity of surface adsorbed water appears to effect nanofiber formation. Fibers as long as 3 microns have been observed, however typical lengths are approximately 400-600 nm (FIG. 1A). Fiber diameters are uniform across all substrates (ca. 35 nm) and appear to be independent of reaction conditions (FIG. 1B). EDX confirms the presence of only carbon, silicon and oxygen on the substrate surface.

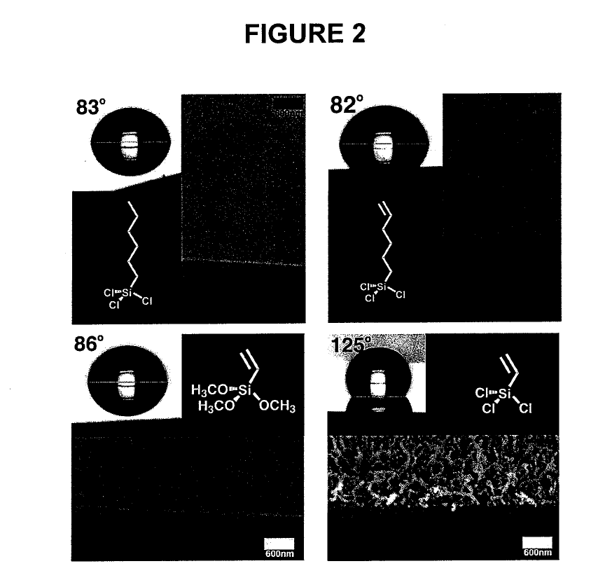

Variable angle FT-IR spectra obtained using an oxygen plasma treated Si(100) wafer background show fibers possess vinyl functionalities (υₛₜᵣ=3062−2958, 1602, 1411, and 1279 cm⁻¹, w), Si—OH (υₛₜᵣ=3600−3100 cm⁻¹, broad), and Si—O—Si linkages (υₛₜᵣ=1156−1000 cm⁻¹, s); suggesting fibers are crosslinked organosiloxane polymers. Supporting this conclusion, TOF-SIMS analyses present fragmentation patterns with mass-to-charge ratios readily assigned to a variety of vinylsiloxane fragments consistent with a polymer structure. While FT-IR and advancing aqueous contact angle (vide infra) data confirmed surface functionalization for substrates exposed to VTMS, HTS, and 5-hexenyltrichlorosilane, no fiber structures were observed by SEM (FIG. 2).

Supporting SEM, EDX, and FT-IR observations, the XP spectra exhibit emissions readily assigned to O(1s), C(1s), Si(1s). The absence of the Cl(2p) clearly indicates full hydrolysis of the Si—Cl bond during the functionalization process and the effective removal of any residual HCl by-products.

Advancing aqueous contact angle measurements provide a direct measure of a substrate surface aqueous wettability (FIG. 2, insets). Hydrophobicity is a function of liquid drop contact area as described by the modified Cassie and Baxter equation,⁴²

cos θ′=ƒcos θ−(1−ƒ) (1)

where, θ′ is the apparent contact angle (CA) on a rough surface, θ is the intrinsic CA on a flat surface, f is the fraction of the solid/water interface, and (1−f) is the fraction of air/water interface. Any increase in the water droplet and solid contact area (i.e., larger f) will increase the aqueous wettability of the rough film surface (i.e., θ′ decreases). From this model, it can be readily deduced that introduction of a fiber structure would serve to increase the substrate roughness and decrease f. The ultimate result of this surface modification is that fiber-bearing surfaces would be more hydrophobic than the flat/smooth counterpart (i.e., a surface functionalized with an equivalent chemical functionality). This is exactly what is observed for the present system. (vide infra)

Upon treatment with RIE, silicon wafers exhibited an advancing aqueous contact angle (θ′) of approximately 0°, consistent with a surface saturated with hydroxyl moieties. After treatment with VTS vapor, fiber-containing substrate surfaces are significantly more hydrophobic (θ′ᵥᵣₛ=137°) than smooth VTMS modified substrates (θ′_{VTMS}=86°) prepared using identical procedures. Clearly, the noted difference in contact angle results solely from the rough fiber structure and highlights the role surface structure plays in a substrate's wetting behavior. To further demonstrate the fundamental importance of surface energy and fiber structure on film wetting, a substrate possessing fibers was annealed at 1000° C. for 1 hour in air. SEM analysis confirmed this annealing process did not compromise the fiber structure, while XPS showed only trace carbon content indicating removal of any vinyl functionality. The resulting fiber structure was found to be very hydrophilic, θ′<5. This result is consistent with reports by Bico et al.⁴³ where the dramatic change in surface wettability arose from both the loss of organic functionality as well as water wetting between the fibers (hemi-wicking). From these observations, it can be concluded that the high contact angle exhibited by the original VTS fibers is the direct consequence of the synergistic influences of high surface area fiber structure and the chemical properties of the surface bonded vinyl moieties.^{36, 44}

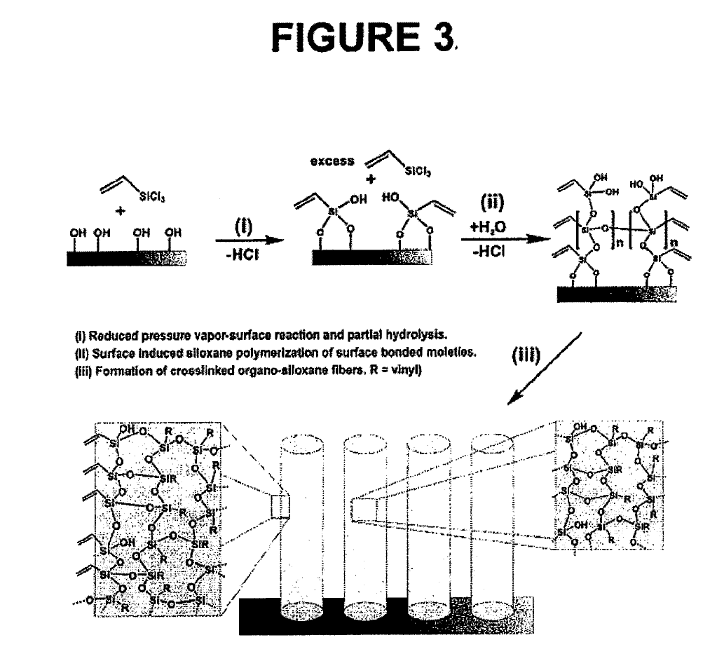

A reasonable mechanism of fiber formation is summarized in FIG. 3. It is well established that OH terminated substrates react with long chain VTSs in solution to form robust, crosslinked, covalently bonded monolayers.^{31, 36, 41, 45} Under anhydrous solution conditions, surface adsorbed water on the substrate promotes hydrolysis of VTSs and subsequent crosslinking of the silanol moieties in the plane of the substrate. When activated substrates are exposed to VTS vapor at reduced pressure, Si—Cl bonds respond in an analogous fashion to solution based methods (FIG. 3(i)). Steric considerations limit siloxane surface bonding to a maximum of two surface linkages for each silicon atom.^{31, 34, 46, 47} As with solution-based reactions, some crosslinking occurs in the plane of the substrate resulting in monolayer formation. The quality of the siloxane monolayer formed on a substrate depends upon the concentration of surface OH groups on the native oxide. These OH groups limit surface diffusion of physisorbed silanol moieties because of the condensation reaction between the vinylsilanols and OH groups on the surface. Decreased surface diffusion results in small islands of non-equilibrium structures forming on the surface of the substrate.⁴⁵ Under these conditions, trace water vapor within the reaction chamber is available to hydrolyze any remaining Si—Cl bonds yielding Si—OH. This Si—OH functionality may further react with VTS to produce organosiloxane chains that assemble to form complex crosslinked fiber structures (FIG. 3(ii),(iii)). Fiber growth was not observed for substrates exposed to VTMS, HTS, and 5-hexenyltrichlorosilane.

Vapor phase PIP affords an effective, straightforward method for introducing 1D nanostructures to substrate surfaces. Spectroscopic analysis highlights that fibers consist of crosslinked organosiloxane polymers that retain chemical functionality which may introduce increased chemical tunability and access to future applications such as bio-receptors, hydrophobic coatings, and sensors. Additionally, sustained fiber morphology after high temperature exposure may make these materials suitable for refractory applications.

### Example 2

### Nanofiber Growth on Si Wafers by the Addition of Water to Previously Dried Substrates

A protocol for the synthesis of nanofibers in the presence of surface adsorbed water is described in Example 1. Contrasting this method, the findings of the present Example were obtained by meticulous attempts to eliminate all surface adsorbed water in the reaction chamber before introducing a predetermined amount of water vapor to the reaction chamber. Briefly, n-doped Si (100) test wafers (1-100 Ω.cm, Evergreen Semiconductor Materials) bearing thermal oxide surfaces were cleaned either by exposure to oxygen plasma (RIE) in a Plasmalab Microetch RIE 80 or a 3:1 mixture of concentrated sulphuric acid and hydrogen peroxide, 30%. Clean, activated substrates were placed in a vacuum oven (125 Torr, >120° C.) for a minimum of two hours prior to modification and left under vacuum until reaction. Vinyltrichlorosilane (VTS), vinyltrimethoxysilane (VTMS), hexyltrichlorosilane (HTS) (Aldrich Chemical Co.), and 5-hexenyltrichlorosilane (Petrach Chemical Co.) were used as received.

When equipment was removed from the oven, it was immediately assembled and placed under vacuum while cooling to prevent further water adsorption. Once cooled to room temperature, the chamber was backfilled to atmospheric pressure and cooled, activated silicon substrates were placed inside a glass chamber with adapted manifold top. The equipment was evacuated again, and while under dynamic vacuum, flame dried to rid of any water additionally adsorbed during the setup stages. Deionized water (50 uL) was injected into the designated flask, and while under static vacuum, evaporated and guided into chamber using direct flame. After a predetermined about of time (T₁), the Si substrate was covered with a tight sealing, custom designed glass shield and 1.5 mmole of VTS vapor was introduced into the reaction vessel. The reaction vessel was then left under static vacuum for another time period to allow the silane time to evaporate (T₂). Finally, the glass shield was raised, exposing the activated substrate to reagent vapor for 1 hour (T₃). Modified substrates were subsequently removed and stored in ambient conditions.

All functionalized wafers were evaluated using scanning electron microscopy (SEM) and energy dispersive X-ray spectroscopy (EDS) using a JOEL 6301F microscope. FT-IR spectroscopy was conducted with a Bruker Vertex 700 Infrared Spectrometer using a “Seagull Variable Angle Accessory”, and X-ray photoelectron spectroscopy (XPS) with a Kratos Axis 165 instrument. Surface aqueous wettability was evaluated with a First Ten Angstroms FTA100 Series contact angle/surface energy analysis system.

As with Example 1, this method also provided well-defined robust nanofibers on the silicon substrates.

### Example 3

### Nanofiber Growth on Kevlar Under Static Vacuum

### (a) Substrate Preparation and Activation

Substrates were activated by the removal of organic contaminants with oxygen plasma reactive ion etch (RIE). For RIE, the plasma chamber was first purged for 30 min with 80% of 100 sccm of O₂ and 75% of 300 W radio frequency at 150 mTorr. The substrate was then treated with the O₂ plasma under similar conditions for 90 sec. Following activation, substrates were placed in a vacuum oven (125 Torr, >120° C.) for a minimum of two hours prior to modification and remained under vacuum until reaction.

### (b) Synthesis

The reaction apparatus was placed in a 150° C. oven for at least 2 hours before being used for a reaction. When equipment was removed from the oven, it was immediately assembled and placed under vacuum while cooling to prevent any water adsorption. Once cooled to room temperature, the chamber was backfilled to atmospheric pressure with Ar and cooled, activated Kevlar® substrates were placed inside the glass chamber with adapted manifold top. The equipment was evacuated again, and while under dynamic vacuum, flame dried to remove any water adsorbed during the assembly stages, before finally leaving the chamber at a static base pressure of 125 Torr. Two Schlenk flasks connected externally to the reaction chamber were backfilled to atmospheric pressure before being charged separately with 2.7 mmol de-ionized water (50 μL) and 1.5 mmol of VTS (200 μL). Next, the de-ionized water flask was opened to the reaction chamber, and water introduced to the chamber by evaporation using direct flame. After a predetermined amount of time (t₁), the Kevlar® substrate was covered with a tight sealing, custom designed glass shield and the VTS vapor was introduced to the reaction vessel by opening the stopcock to the silane reagent Schlenk flask. After a second induction time, (t₂), which allowed the silane reagent adequate time to evaporate, the glass shield was raised, exposing the activated substrate to reagent vapor (t₃). Standard reaction times were t₁=5 min, t₂=10 min, t₃=60 min. Modified substrates were subsequently removed and stored in ambient conditions.

### (c) Results

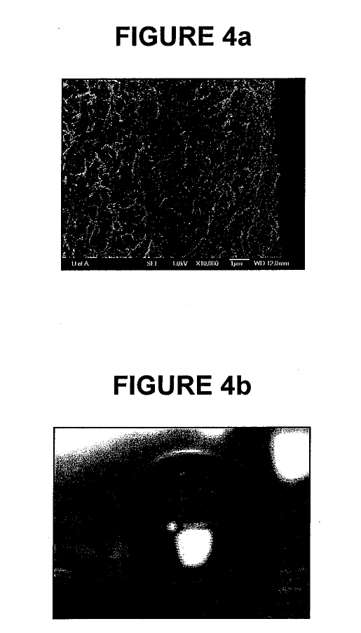

Various forms of Kevlar® (greige, scoured, poly(ethylene glycol) coated, and uni-dimensional) were screened. To assess feasibility, a greige sample was reactive ion etched (RIE) in an oxygen plasma then placed in the static vacuum deposition apparatus and exposed to vinyltrichlorosilane (VTS). FIG. 4a shows a scanning electron micrograph (SEM) highlighting the abundant polysiloxane nanofiber growth on greige fabric. FIG. 4b is a photograph of a water droplet beading on the surface of the nanofiber coated greige sample. Water beading on the fiber-bearing fabric is a stark contrast to the complete absorption typically observed on a bare greige substrates. From these results, it is evident that greige Kevlar® is an appropriate substrate for polysiloxane nanofiber formation.

### Example 4

### Nanofiber Growth on Kevlar® Substrates Under Continuous Flow

### (a) Substrate Preparation

Organic contamination was removed from the surface of the Kevlar® substrate using oxygen plasma reactive ion etching (RIE). For RIE, the plasma chamber was first purged for 30 min with 80% of 100 sccm of O₂ and 75% of 300 W radio frequency at 150 mTorr. The substrate was then treated with the O₂ plasma under similar conditions for 90 sec. Substrates cleaned in H₂O₂ were submerged in the peroxide for 1 min then removed and rinsed with copious amounts of distilled H₂O. After either method of cleaning, the substrates were then placed in a vacuum oven (125 Torr, 120° C.) for >1 h. The substrates, once dried, were placed in a humidity controlled environment until the appropriate weight (0-10)% H₂O is adsorbed or used immediately.

Substrates that were utilized in the present study included greige, scoured, unidimensional (UD) (specifically UD 0/90) and polyethylene glycol (PEG)-treated Kevlar®.

### (b) Synthesis

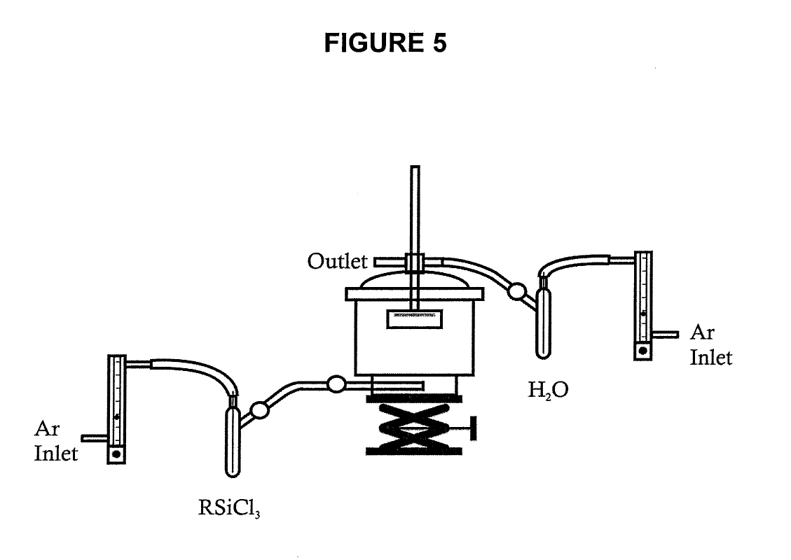

FIG. 5 is a schematic of the small-scale continuous flow apparatus for use at 1 atm. The VTS inlet to the apparatus was located at the bottom of the apparatus and the outlet at the top. Gas entering this inlet was a mixture of VTS and Ar. This mixture as obtained by bubbling Ar through a neat solution of VTS. VTS was consumed at a rate of ˜0.001-0.4 mL/h.

Water required for hydrolysis of the VTS as introduced to the chamber using one of two methods. To obtain a beaded surface morphology, or short (<300 nm), large diameter (>50 nm) fibers, 0-5 wt % H₂O Kevlar samples were placed in the chamber. Alternatively, fibers were obtained by flowing wet Ar through the reaction chamber concomitantly with Ar containing VTS. Wet Ar was obtained by bubbling Ar through distilled H₂0. The H₂0 rate of consumption was ˜0.00-0.5 mL/h.

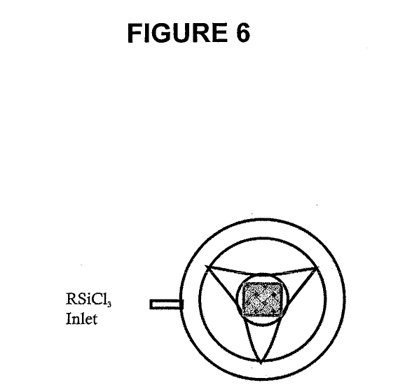

The substrate was placed at a distance of 4-12 cm away from the VTS/Ar inlet. This as accomplished by one of two methods: 1. The substrate is mounted to the underside of a movable stage (FIG. 5) or 2. Placed on a watch glass and positioned in the centre of a triangular shelf (FIG. 6).

Kevlar® samples exhibiting high contact angles on both sides of the substrate were obtained by placing the fabric sample on a watch glass ensuring a visible gap between the sides of the Kevlar® and the glass exists. The watch glass was then placed in the apparatus as shown in FIG. 5.

### (c) Results

At 125 Torr, the operating pressure in the static, batch system described in Examples 1-3, the boiling point of VTS is 37.6° C. The decreased operating pressure enables VTS to evaporate and enter the reaction chamber at a much quicker rate than at atmospheric pressure. VTS is a volatile compound with a boiling point of 90° C. at atmospheric pressure. A reaction proceeding under these conditions requires a much longer time to complete compared to reduced pressure because of the slower evaporation rate and hence lower VTS vapor concentration in the chamber. To increase the VTS rate of addition at atmospheric pressure and decrease reaction time, a carrier gas, Ar, was used to transport VTS into the reaction chamber. This was accomplished by bubbling the carrier gas through a neat solution of VTS.

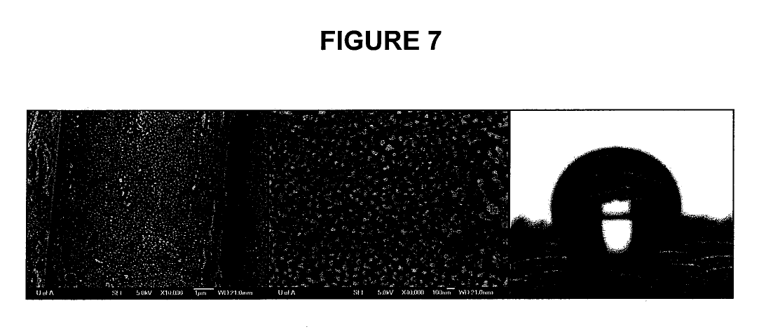

Switching to a continuous stream of VTS altered the reaction dynamic inside the chamber. More specifically, the VTS:H₂O ratio changed. From previous control studies conducted using Si substrates in the static vacuum apparatus, it was learned that high density nanofibers >500 nm in length form when a ratio of ca. 1 VTS: 2 H₂O exists within the chamber. To re-establish this ratio, a second Ar stream bubbled through distilled H₂O was fed into the reaction chamber simultaneously (see FIG. 5). Without the H₂O/Ar, fiber growth was stunted. Substrates exposed to the VTS/Ar stream in the absence of the H₂O/Ar stream are shown in FIG. 7a-c. The small fibers seen in the SEMs were formed using native water adsorbed from the atmosphere onto the scoured Kevlar® before exposure to the organosilane vapor. Although the fibers were only ˜200-300 nm long, the sample appeared qualitatively to be as hydrophobic as that shown in FIG. 4a.

Nanofibers were successfully grown on RIE'd, scoured substrates using VTS/Ar with H₂O/Ar (FIG. 7). Again, the fiber bearing substrates exhibited advancing and receding contact angles (θₐ, θᵣ)>90°.

### Example 5

### Reaction Chamber Scale-Up Design

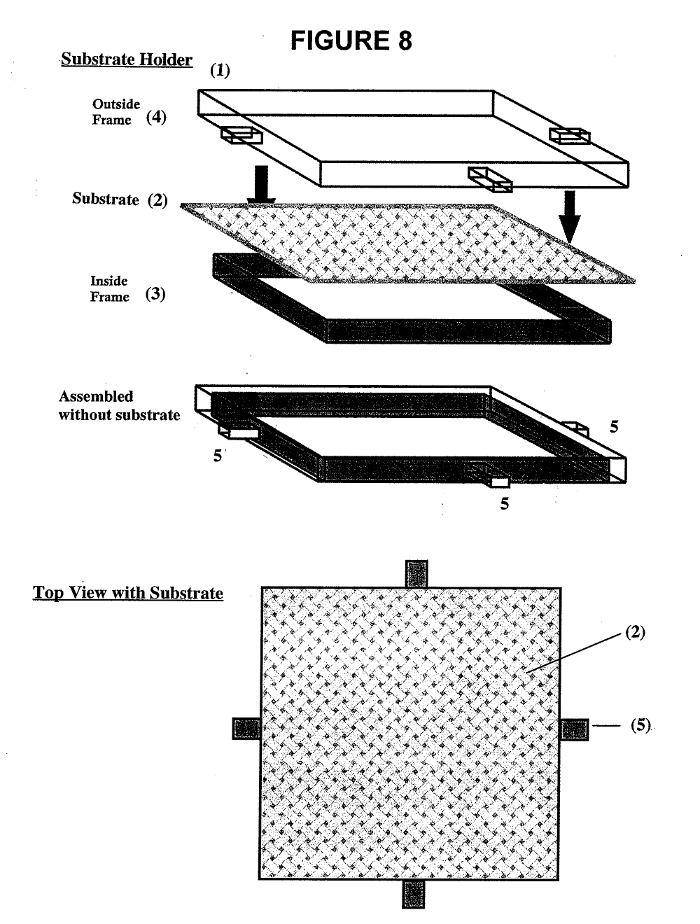

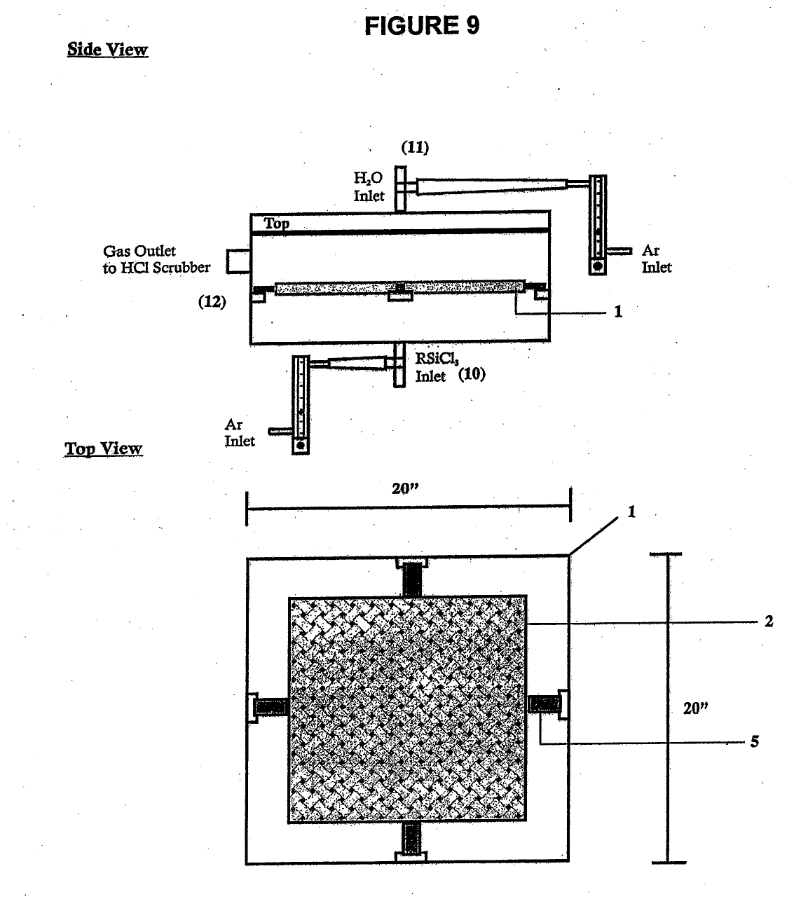

FIGS. 8-11 are drawings of intermediate sized reaction chambers. FIG. 8 is an illustration of the substrate holder (1) used to support the substrate (2) in each FIGS. 9, 10 and 11. This holder is particularly useful in when the substrate is fabric, such as Kevlar®. The substrate holder (1) comprises an inner (3) and outer (4) frame. The outer frame (4) has four pegs (5) on the periphery which support it when placed in the reaction chamber. To assemble the holder, a square piece of substrate (for example, 17″×17″) is placed between the outer (4) and inner (3) frame. The outer frame (4) is then pushed down onto the substrate (2) and the inner frame (3) until the substrate (2) becomes taut.

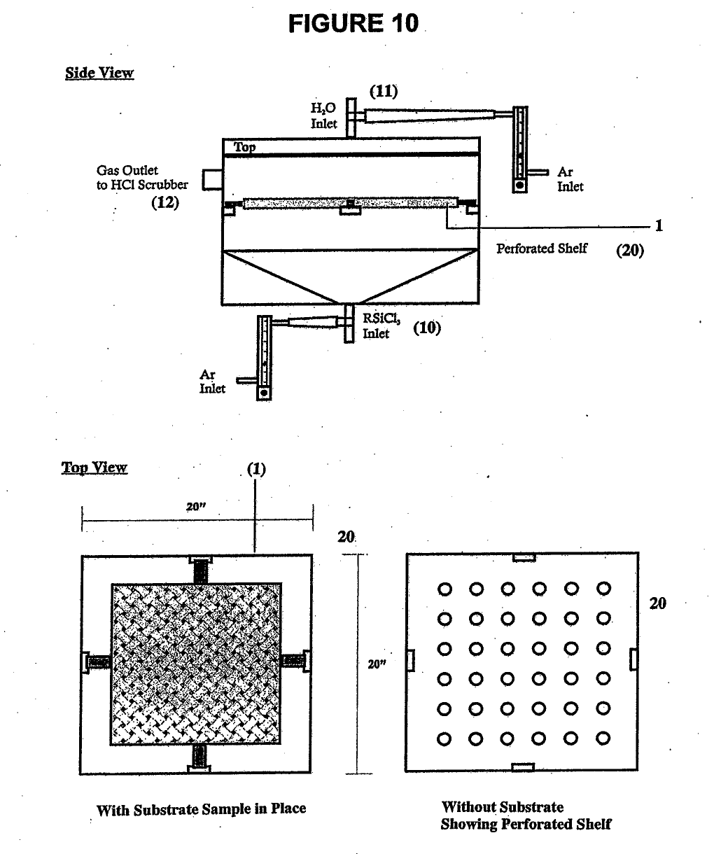

In FIG. 9 the RSiCl₃ (10) and H₂O (11) inlets are in similar positions to those used in the small-scale apparatus (FIG. 5). The outlet (12) to this apparatus is placed on the side instead of at the top as in the small apparatus (FIG. 5). Polysiloxane formation in the top cylinder of the small apparatus between the H₂O inlet and the gas outlet was observed. By moving the gas outlet closer to the substrate, RSiCl₃ polymerization may be decreased at the apparatus surface, while promoting polymerization at the substrate. An alternate design in FIG. 10 differs from FIG. 9 by the inclusion of a perforated shelf (20). This shelf serves to distribute the RSiCl₃ vapor evenly to the substrate surface.

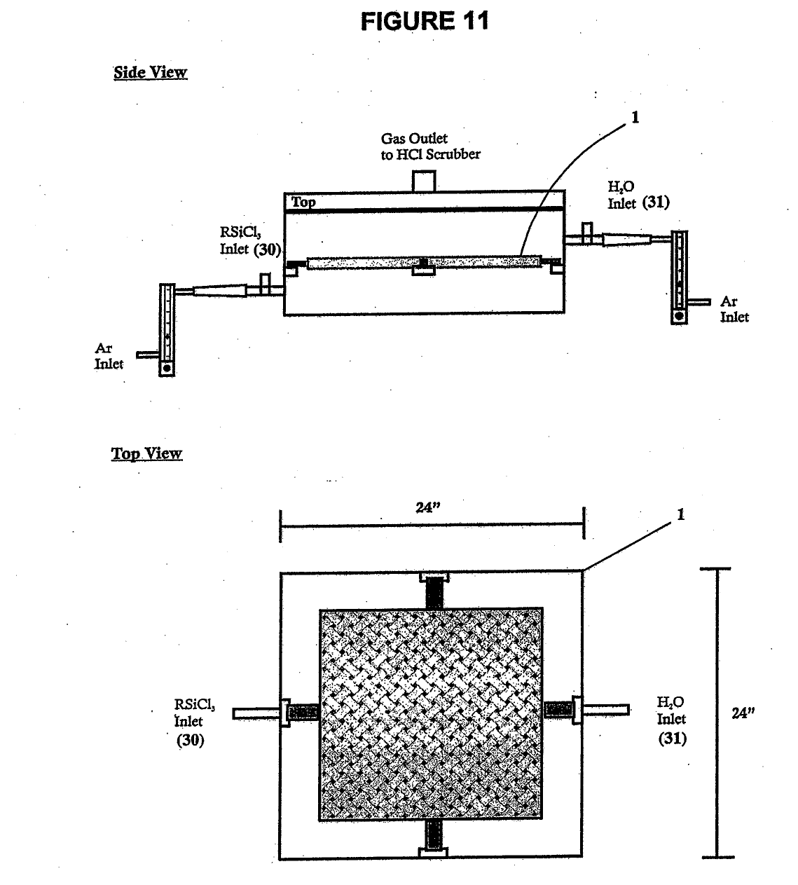

The RSiCl₃ (30) and H₂O (31) inlet positions are moved to opposite horizontal sides of the apparatus in FIG. 11. Positioning the inlets on the sides of the apparatus as opposed to top and bottom inlets offers a simpler bench top set up.

While the present disclosure has been described with reference to what are presently considered to be the preferred examples, it is to be understood that the disclosure is not limited to the disclosed examples. To the contrary, the disclosure is intended to cover various modifications and equivalent arrangements included within the spirit and scope of the appended claims.

All publications, patents and patent applications are herein incorporated by reference in their entirety to the same extent as if each individual publication, patent or patent application was specifically and individually indicated to be incorporated by reference in its entirety. Where a term in the present application is found to be defined differently in a document incorporated herein by reference, the definition provided herein is to serve as the definition for the term.

### FULL CITATIONS FOR DOCUMENTS REFERRED TO IN THE SPECIFICATION

1. Huang, M. H.; Mao, S.; Feick, H.; Yan, H.; Wu, Y.; Kind, H.; Weber, E.; Russo, R.; Yang, P., Science 2001, 292, 1897-1900.
2. Xia, Y.; Yang, P.; Sun, Y.; Wu, Y.; Kim, F.; Yan, H., Adv. Mater. 2003, 15, 353-389.
3. Arnold, M. S.; Avouris, P.; Wei Pan, Z.; Wang, Z. L., Journal of Physical Chemistry B. 2002, 107, 659-663.
4. Cui, Y.; Lieber, C. M., Science 2001, 291, 851-854.
5. Cui, Y.; Wei, Q.; Park, H.; Lieber, C. M., Science 2001, 293, 1289-1293.
6. Jang, J.; Chang, M.; Yoon, H., Adv. Mater. 2005, 17, 1616-1620.
7. Virji, S.; Huang, J.; Kaner, R. B.; Weiller, B. H., Nano Lett. 2004, 4, 491-496.
8. Yu, D. P.; Hang, Q. L.; Ding, Y.; Zhang, H. Z.; Bai, Z. G.; Wang, J. J.; Zou, Y. H.; Zian, W.; Xiong, G. C.; Feng, S. Q., Appl. Phys. Lett. 1998, 73, 3076-3078.
9. Zheng, B.; Wu, Y.; Yang, P.; Liu, J., Adv. Mater. (Weinheim, Fed. Repub. Ger.) 2002, 14, 122-124.
10. Carter, J. D.; Qu, Y.; Porter, R.; Hoang, L.; Masiel, D. J.; Guo, T., Chemical Communications 2005, 2274-2276.
11. Hu, J. Q.; Jiang, Y.; Meng, X. M.; Lee, C. S.; Lee, S. T., Chem. Phys. Lett. 2003, 367, 339-343.
12. Verheijen, M. A.; Immink, G.; de Smet, T.; Borgstrom, M. T.; Bakkers, E. P. A. M., J. Am. Chem. Soc. 2006, 128, 1353-1359.
13. Wang, X.; Ding, Y.; Summers, C. J.; Wang, Z. L., J. Phys. Chem. B 2004, 108, 8773-8777.
14. Jang, J.; Bae, J.; Park, E., Adv. Funct. Mat. 2006, 16, 1400-1406.
15. Zhang, M.; Bando, K.; Wada, K.; Kurashima, K., J. Mater. Sci. Lett. 1999, 18, 1911-1913.
16. Yu, T.; Joo, J.; Park, Y. I.; Hyeon, T., J. Am. Chem. Soc. 2006, 128, 1786-1787.
17. Li, D.; Xia, Y., Nano Lett. 2003, 3, 555-560.
18. Deitzel, J. M.; Kleinmeyer, J. D.; Hirvonen, J. K.; Tan, N. C. B., Polymer 2001, 42, 8163-8170.
19. Doshi, J.; Reneker, D. H., Journal of Electrostatics 1995, 35, 151-160.
20. Kameoka, J.; Verbridge, S. S.; Jiu, H.; Czaplewski, D. A.; Craighead, H. G., Nano Lett. 2004, 4, 2105-2108.
21. Jeong, H. E.; Lee, S. H.; Kim, P.; Suh, K. Y., Nano Lett. 2006, 6, 1508-1513.
22. Abu-Lail, N. I.; Kaholek, M.; LaMattina, B.; Clarck, R. L.; Zauscher, S., Sensors and Actuators B 2006, 114, 371-378.
23. Kim, J. W.; Chung, C. W.; Rhee, Y. H., International Journal of Biological Macromolecules 2005, 35, 47-53.
24. Bae, J.-S.; Seo, E.-J.; Kang, I.-K., Biomaterials 1999, 20, 529-537.
25. Seino, M.; Yokomachi, K.; Hayakawa, T.; Kikuchi, R.; Kakimoto, M.-a.; Horiuchi, S., Polymer 2006, 47, 1946-1952.
26. Gupta, B.; Hilborn, J. G.; Bisson, I.; Frey, P., J. Appl. Polym. Sci. 2001, 81, 2993-3001.
27. Gupta, B.; Anjum, N., Adv. Polym. Sci. 2003, 162, 36-61.
28. Bae, B.; Ha, Y. H.; Kim, D., Journal of Membrane Science 2006, 276, 51-58.
29. Zhong, S.; Meng, Y.; OU, Q.; Shu, Z., Plasma Science & Technology 2006, 8, 321-324.
30. Nguyen, V.; Yoshida, W.; Cohen, Y., J. Appl. Polym. Sci. 2003, 87, 300-310.
31. Sagiv, J., J. Am. Chem. Soc. 1980, 102, 92-98.
32. Popat, K. C.; Johnson, R. W.; Desai, T. A., Surface and Coatings Technology 2002, 154, 253-261.
33. Bunker, B. C.; Carpick, R. W.; Assink, R. A.; Thomas, M. L.; Hankins, M. G.; Voigt, J. A.; Sipola, D.; de Boer, M. P.; Gulley, G. L., Langmuir 2000, 16, 7742-7751.
34. Wasserman, S. R.; Tao, Y.-T.; Whitesides, G. M., Langmuir 1989, 5, 1074-1087.
35. Yoshida, W.; Castro, R. P.; Jou, J.-D.; Cohen, Y., Langmuir 2001, 17, 5882-5888.
36. Tsoi, S.; Fok, E.; Sit, J. C.; Veinot, J. G. C., Langmuir 2004, 20, 10771-10774.
37. Wang, Y.; Ferrari, M., J. Mat. Sci 2000, 35, 4923-4930.
38. Schwartz, D. K.; Steinberg, S.; Israelachvili, J.; Zasadzinski, J. A. N., Phys. Rev. Lett. 1992, 69, 3354-3357.
39. Popat, K.; Sharma, S.; Johnson, R. W.; Desai, T. A., Surf. Interface Anal. 2003, 35, 205-215.
40. No effort was made to free the reaction chamber of surface adsorbed water.
41. Silberzan, P.; Léger, L.; Ausserre, D.; Benattar, J. J., Langmuir 1991, 7, 1647-1651.
42. Cassie, A. B. D.; Baxter, S., Transcations of Faraday Society 1944, 40, 546-551.
43. Bico, J.; Thiele, U.; Quéré, D., Colloids and Surfaces A: Physicochem. Eng. Aspects 2002, 2006, 4146.
44. Tsoi, S.; Fok, E.; Sit, J. C.; Veinot, J. G. C., Chem. Mater. 2006, 18, 5260-5266.
45. Brunner, H.; Vallant, T.; Mayer, U.; Hoffmann, H., Langmuir 1999, 15, 1899-1901.
46. Finklea, H. O.; Robinson, L. R.; Blackburn, A.; Richter, B., Langmuir 1986, 2, 239-244.
47. Senaratne, W.; Andruzzi, L.; Ober, C. K., Biomacromolecules 2005, 6, 2427-2448.
48. Zimmerman, J.; Seeger, S.; Artus, G.; Jung, S. PCT Patent Application Publication No. WO2004/113456.

We claim:

1. A method of coating an oxide substrate with organosiloxane nanofibers comprising exposing an activated substrate to vapor comprising vinyltrichlorsilane under conditions for the formation of the organosiloxane nanofibers

2. The method according to claim 1, wherein the activated oxide substrate is obtained by treating under conditions to activate surface functional groups for reaction with the vinyltrichlorosilane and wherein the conditions to activate surface functional groups comprise saturating the surface with hydroxyl moieties.

3. The method according to claim 2, wherein the conditions to activate surface functional groups comprise exposure to oxygen plasma or placement in a piranha bath.

4. The method according to claim 1, wherein the substrate is selected from metal, silicon-based materials, titanium-based materials, germanium-based materials, aluminum-based materials, biodegradable materials, construction materials, inorganic materials and organic materials.

5. The method according to claim 4, wherein the substrate is selected from silicon wafers, titanium wafers, germanium wafers, fiber optic cables, capillary tubes, colloidal beads, glass, ceramics, paper, wood, fabrics, cellulose, cellulose derivatives, semiconductors, stone, concrete, marble, bricks and tiles.

6. The method according to claim 5, wherein the substrate is a silicon wafer.

7. The method according to claim 5, wherein the substrate is fabric.

8. The method according to claim 7, wherein the fabric is comprised of aromatic polyamides fibers.

9. The method according to claim 8, wherein the fabric comprises para-aramid synthetic fibers, comprises meta-aramid synthetic fibers or comprises aromatic copolyamid fibers.

10. The method according to claim 9 wherein the fabric comprises para-aramid synthetic fibers.

11. The method according claim 1, wherein the conditions for the formation of the organosiloxane nanofibers comprises exposing the substrate to vinyltrichlorosilane vapor in an inert atmosphere without the exclusion of surface adsorbed water.

12. The method according to claim 1, wherein the conditions for the formation of the organosiloxane nanofibers comprise drying a reaction vessel, drying an activated substrate, inserting the substrate in the vessel under an inert atmosphere and maintaining said inert atmosphere, adding an effective amount of water to the vessel and allowing water vapor to equilibrate, reducing the pressure in the reaction vessel, adding the substrate to the vessel and exposing the substrate to vinyltrichlorosilane vapor.

13. The method according to claim 12, wherein the substrate is exposed to vinyltrichlorosilane vapor at a reaction pressure from about 100 Torr to about 150 Torr.

14. The method according to claim 12, wherein the substrate is exposed to the vinyltrichlorosilane vapor for about 0.15 hour to about 1.5 hours.

15. The method according to claim 12, wherein the concentration of vinylchlorosilane is from about 0.034 mmol/cm² to about 1 mmol/cm².

16. The method according to claim 1, wherein, the conditions for the formation of the organosiloxane nanofibers comprise drying a reaction vessel, drying an activated substrate, inserting the substrate in the vessel under an inert atmosphere and maintaining said inert atmosphere, adding a suitable amount of water to the reaction vessel, either prior to, or simultaneously with, adding the vinyltrichlorosilane to the reaction vessel via a carrier gas that has been passed through a solution of the vinyltrichlorosilane.

17. A substrate coated with silicone nanofibers prepared from vinyltrichlorosilane.

18. The substrate according to claim 17, having a diameter of about 20 nm to about 70 nm.

19. The substrate according to claim 17 wherein the substrate has an advancing aqueous contact angle of about 90° to about 140°.

20. The substrate according claim 17, comprising a wetting layer on the surface of the substrate.

21. The substrate according claim 17, wherein the silicone nanofiber coating has a thickness of about 100 nM to about 8 μM.

22. A substrate prepared using the method according claim 1.

23. The method according claim 1, further comprising reacting the coated substrate under conditions for the attachment of a molecule of interest to the substrate via reaction with the vinyl group from the vinyltrichlorosilane.

24. The method according to claim 23, wherein the molecule of interest is a biomolecule, nanoparticle or polymer.

25. A method of preparing hydrophilic siloxane nanofibers on a substrate comprising
(a) obtaining a substrate coated with organosiloxane nanofibers; and
(b) calcining the substrate under conditions to remove substantially all of the organic portions of the organosiloxane nanofibers.

31. The method according to claim 25, wherein the conditions to remove substantially all of the organic portions of the organosiloxane nanofibers include heating at temperatures ranging from about 380° C. to about 500° C., for about 0.5 26 ur to about 1.5 hours, in air.
